(19) United States
(12) Patent Application Publication
(10) Pub. No.: US 2008/0303121 A1
(43) Pub. Date: Dec. 11, 2008

(54) Integrated Electronic Circuitry and Heat Sink

(75) Inventors: Jenshan Lin, Gainesville, FL (US); Fan Ren, Gainesville, FL (US); Stephen J. Pearton, Gainesville, FL (US); Travis J. Anderson, Gainesville, FL (US); Brent P. Gila, Gainesville, FL (US)

Correspondence Address: AKERMAN SENTERFITT, P.O. BOX 3188, WEST PALM BEACH, FL, 33402-3188, US

(73) Assignee: University of Florida Research Foundation, Inc., Gainesville, FL (US)

(21) Appl. No.: 11/916,910

(22) PCT Filed: May 31, 2006
(86) PCT No.: PCT/US06/21420

§ 371 Date: Jul. 7, 2008

Related U.S. Application Data
(60) Provisional application No. 60/688,034, filed on Jun. 7, 2005.

(51) Int. Cl. H01L 23/34; H01L 23/50

(52) U.S. Cl. 257/664; 257/706; 257/E23.08; 257/E23.079

(57) ABSTRACT

A multi-layer heatsink module for effecting temperature control in a three-dimensional integrated chip is provided. The module includes a high thermal conductivity substrate having first and second opposing sides, and a gallium nitride (GaN) layer disposed on the first side of the substrate. An integrated array of passive and active elements defining electronic circuitry is formed in the GaN layer. A metal ground plane having first and second opposing sides is disposed on the second side of the substrate, with the first side of the ground plane being adjacent to the second side of the substrate. A dielectric layer of low thermal dielectric material is deposited on the back side of the ground plane, and a metal heatsink is bonded to the dielectric layer. A via extends through the dielectric layer from the metal heatsink to the metal ground plane.

### FIELD OF THE INVENTION

The present invention is related to the field of integrated circuits, and, more particularly, to integrated circuits that combine electronic processing functionality with heat dissipation capabilities.

### BACKGROUND OF THE INVENTION

The extraordinary advances made in communication and computing technologies over the last 40 years stem, in large measure, from the advent of integrated circuit “chips.” Integrated circuit chips have lead to ever smaller sizes and ever faster speeds for processing electrical signals and signals-based information. Laptop computers, personal digital assistants (PDAs), mobile phones, and a host of other electronic devices are capable of performing more functions, more rapidly, and less expensively as a result of chip-based technologies.

The “stacking” of chip layers by layering active wafers on top of a base layer of silicon has been a particularly important step in advancing communication and computing technologies. For example, one approach to achieving high power density and increased functionality in communication chips is to use a three-dimensional (3-D) integration of gallium nitride (GaN) and silicon (Si) components as a multi-layer or multi-chip module. Si devices are typically much more sensitive to temperature than are GaN devices. As a result, the performance of a Si device generally undergoes significant degradation at temperatures exceeding 100° C. The need to manage the thermal conditions in the Si layer, accordingly, is frequently an overriding determinant of the ultimate power density that can be achieved with 3-D integrated multi-chip module.

High electron-mobility transistors (HEMT) comprising Aluminum Gallium Nitride/Gallium Nitride (AlGaN/GaN) layers are generally capable of providing very high power density, typically exceeding 10 watts per millimeter (W/mm). This high power density, however, creates very high local temperatures—often in excess of 125° C.—on a chip. Moreover, traditional heatsink design concepts typically do not work well with respect to such hot spots.

The well-known mechanism of heat transfer from heatsink to ambient is through heat convection. According to the relevant governing equation, the heat convection is mathematically represented as Q=h×A×ΔT, where Q is the heat transfer, where h is the convection coefficient, A is the area of heat transfer, and ΔT is the temperature difference between heatsink and the ambient temperature. Conventional metal heatsinks have good thermal conductivity, and the temperature rise within the heatsink is usually quite small. Therefore, a relatively large temperature difference, ΔT, can be accommodated using a conventional heatsink.

A persistent problem with the application of conventional approaches to integrated circuit chips, however, is that the area in which a high temperature difference, ΔT, occurs is very small. The result is a very small value of heat convection, Q. Accordingly, there remains the need for a mechanism by which the temperature of a 3-D package can be controlled more effectively. Specifically, there is a need to control 3-D package temperature so that the electronics of both the GaN and Si layers of the stacked-layer integrated device can be operated without undue temperature constraints resulting from temperature-based degradation in the Si layer.

The need to effectively control temperature in an integrated circuit can be a particular concern with respect to integrated circuits that have radio frequency (RF) functionality, such functionality typically being provided by an RF transceiver and antenna. It is desirable in such circuits to position the antenna close to the RF transceiver, since it is the RF transceiver that performs the needed functions for processing RF signals transmitted and received via the antenna.

Structurally, such integrated circuits are typically implemented in high-density, 3-D packages. As already noted, a frequent concern with such a structure is heat generation—in particular, the heat generated by the high-power amplifier needed to amplify received or transmitted signals. The concern is that if the heat traverses other layers of the package before being sufficiently dissipated, other portions of the electronic circuitry that are more temperature sensitive are very likely to be adversely affected, if not destroyed altogether or otherwise rendered inoperable. Thus, it is generally necessary to somehow protect both the baseband electronics and the RF electronics from excessive thermal energy in order to avoid the destruction or inoperability of the RF device.

Not surprisingly, therefore, heat generation and its dissipation are significant challenges to designers of high-density 3-D RF devices. A thermal insulation layer can provide heat shielding for baseband silicon-based electronics in the device. With respect to the portion of the device containing the RF electronics, however, the inclusion of the power amplifier can make limiting the amount of heat problematic. Nonetheless, if the heat is not sufficiently dissipated, it can adversely effect and possibly damage or destroy the RF electronics.

It follows that there also is a need for an effective and efficient way to deal with temperature-related problems while also accommodating the objective of keeping the RF device compact. More particularly, there is a need for a structure or mechanism that enhances heat dissipation in the RF device but does so without using an undue amount of the otherwise limited real estate of the chip or semiconductor in which the RF device is packaged.

### SUMMARY OF THE INVENTION

The present invention is directed to systems and electronic-based packages or modules that more effectively and efficiently mitigate temperature effects in 3-D “chip” packages. More particularly, the invention can provide enhanced heat dissipation in both the GaN and Si layers of a stacked-layer integrated device. Accordingly, the invention can enable the operation of such devices without undue temperature constraints that otherwise result from temperature-based degradation in the Si layer.

One embodiment of the invention is a multi-layer heatsink module for effecting temperature control in a 3-D integrated chip. The module can include a high thermal conductivity substrate having first and second opposing sides. A gallium nitride (GaN) layer can be disposed on the first side of the substrate. An integrated array of passive and active elements defining electronic circuitry can be formed in the GaN layer. A metal ground plane can be disposed on the second side of the substrate, the metal ground plane having first and second opposing sides, with the first side of the ground plane being adjacent to the second side of the substrate. A dielectric layer of low thermal dielectric material can be deposited on the back side of the ground plane. A metal heatsink can be bonded to the dielectric layer. At least one via can extend through the dielectric layer from the metal heatsink to the metal ground plane.

Another embodiment of the invention is a communications module. The module can include a semiconductor substrate having first and second opposing sides. A baseband layer comprising baseband circuitry and an RF layer adjacent the baseband layer comprising RF circuitry can be formed within the substrate. A GaN layer can be disposed on the first side of the substrate, and at least one power amplifier can be formed within the GaN layer. A metal ground plane having first and second opposing sides can be disposed on the second side of the substrate, the first side of the ground plane being adjacent to the second side of the substrate. A dielectric layer of low thermal dielectric material can be deposited on the back side of the ground plane. An dual-function heatsink-antenna structure can be bonded to the dielectric layer, and at least one via can extend from the dual-function heatsink-antenna structure through the dielectric layer to the metal ground plane.

Yet another embodiment is a data processing module. The data processing module can include a semiconductor substrate having first and second opposing sides. An integrated array of passive and active elements comprising data processing circuitry defining a central processing unit (CPU) can be formed in the substrate. A GaN layer can be disposed on the first side of the substrate. At least one power amplifier can be formed within the GaN layer. A metal ground plane can be disposed on the second side of the substrate, the ground plane also having first and second opposing sides. The first side of the ground plane can be positioned adjacent the second side of the substrate. A dielectric layer of low thermal dielectric material can be deposited on the back side of the ground plane, and a metal ground plane can be bonded to the dielectric layer. At least one via can extend through the ground plane and dielectric layer to the semiconductor substrate for optionally and selectively connecting the central processing unit to an external component.

According to still another embodiment, a data processing module can include a first ground plane connected to a first side of a substrate in which circuitry defining a CPU is formed. A GaN layer including at least one power amplifier formed therein can be connected to an opposing side of the substrate. A dielectric layer can be deposited on the first ground plane and a second ground plane bonded to the dielectric layer. A heatsink can be connected to the second ground plane.

### BRIEF DESCRIPTION OF THE DRAWINGS

There are shown in the drawings, embodiments which are presently preferred. It is noted, however, that the invention is not limited to the precise arrangements and instrumentalities shown in the drawings.

FIG. 1 is a cross-sectional view of a multi-layer heatsink module, according to one embodiment of the invention.

FIG. 2 is a cross-sectional view of a communications module, according to another embodiment of the invention.

FIG. 3 is a perspective view of a plurality of dual-function heatsink-antenna extensions, according to yet another embodiment of the invention.

FIG. 4 is a cross-sectional view of a data processing module, according to yet another embodiment of the invention.

FIG. 5 is a cross-sectional view of another processing module, according to a different embodiment of the invention.

FIG. 6 is schematic view of an integrated circuit for effecting RF communications and having integrated therein a dual-function antenna-heatsink combination, according to another embodiment of the invention.

FIG. 7 is a cross-sectional view of an integrated circuit for effecting RF communications and having integrated therein a dual-function antenna-heatsink, according to yet another embodiment of the invention

### DETAILED DESCRIPTION

The present invention provides mechanism for effecting temperature control in a three-dimensional (3-D) integrated chip. As discussed herein, the invention has broad applicability and can be used in a variety of settings for a multitude of different purposes.

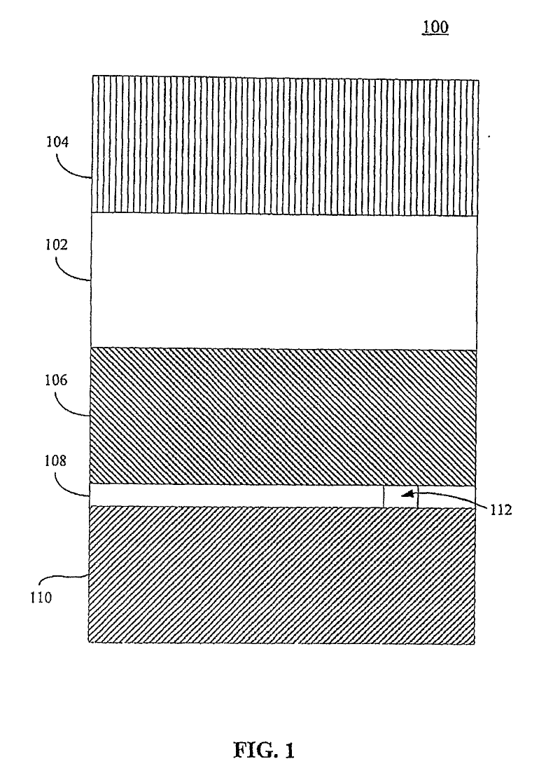

FIG. 1 is a schematic representation of a cross section of a multi-layer heatsink module 100, according to one embodiment of the invention. The multiple heatsink system 100 illustratively includes a high thermal conductivity substrate 102 having first and second opposing sides. A gallium nitride (GaN) layer 104 is disposed on the first side of the substrate 102. An integrated array of passive and active elements, the elements defining electronic circuitry (not explicitly shown), can be formed within the layer. The electronic circuitry can be fabricated using various known chip fabrication techniques.

The module 100 further illustratively includes a metal ground plane 106 disposed on the second side of the substrate 102. The metal ground plane 106, as shown, also has first and second opposing sides. The first side of ground plane 106 is adjacent to the second side of the substrate 102, as also shown. A dielectric layer 108 is deposited on the back side of the ground plane 106, and a metal heatsink 110 is bonded to the dielectric layer. As further illustrated, at least one via 112 extends through the dielectric layer 108, the via extending from the metal heatsink 110 to metal ground plane 106. The role served by the via is described more particularly below.

The high thermal conductivity substrate 102, according to one embodiment, comprises a silicon-based material. Preferably, the silicon-based material from which the substrate is formed is silicon carbide (SiC).

The dielectric layer 108 deposited on the back side of the ground plane 106 comprises a low thermal dielectric material. For example, dielectric material can be silicon oxide (SiO₂). Alternatively, the dielectric material can be titanium oxide (TiO₂). Still other dielectric materials can alternately be used in accordance with the invention.

Preferably, the thickness of the dielectric material lies within a range from 0.2 nanometers (0.2 nm) to one-half a micrometer (0.5 μm). More preferably, the thickness of the dielectric material is (0.3 μm), within a relatively small deviation of less than plus or minus one-tenth a nanometer.

The thinness of the dielectric layer 108 can mitigate, or control, heat that is generated in other layers of the module 100 during operation of the electronic circuitry. The dielectric layer 108, more particularly, can cause the generated heat to diffuse or fan out laterally. The result is an increase in the effective area through which heat transfer occurs with the module 100. In some simulated heat transfers comparing the module of the invention to those of conventional design, device-junction temperature with the module has been reduced by as much as 30-40° C.

As already noted, the invention can be used for a variety of purposes in different embodiments. For example, there is a strong and growing interest in wide bandgap devices for use in microwave power transmission systems to which the invention has applicability. High Electron Mobility Transistors (HEMTs) transistors may provide high-performance millimeter-wave (MMW) military communications links and X-band radar systems. Military applications of RF transmitters and receivers such as all-weather radar, surveillance, reconnaissance, electronic attack, and communications systems may be developed with these electronic elements. GaN-based components and circuitry, more particularly, can operate from VHF through X-band frequencies while also providing higher breakdown voltages, as well as better thermal conductivity and wider transmission bandwidths than conventional devices.

GaN transistors with the same dimensions as currently used GaAs devices can operate at higher powers with higher impedance. Within the field of RF applications, particularly, MMW communications links and X-band radar are two significant . A limitation on the development of such devices, however, is likely to be the need to effectively and efficiently control the heat generated in such devices. It is here that the invention has particular applicability. The invention will also have applications in future computer processors (e.g. CPU) where enormous heat is generated and a heatsink has to be directly attached to the CPU chip. The invention will help minimize the temperature rise of the CPU chips. The various applications of the invention are illustrated by the embodiments described below.

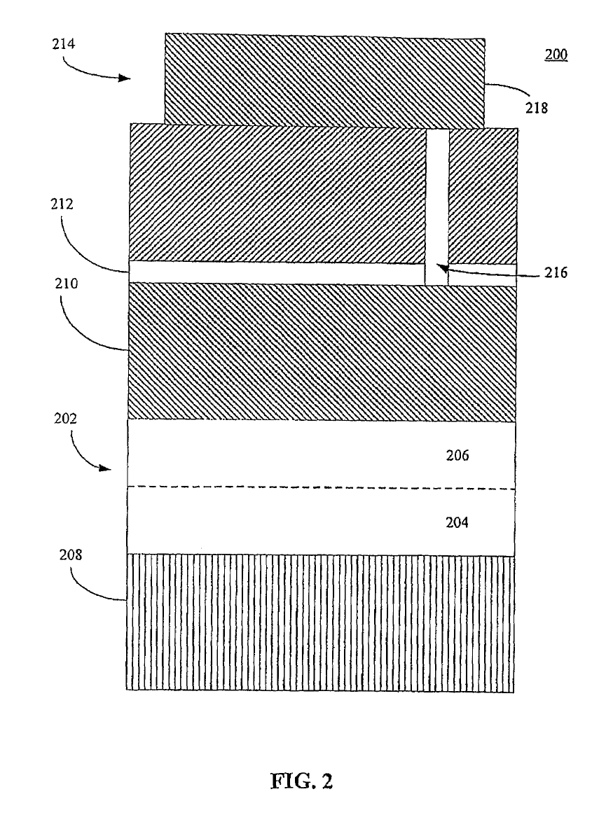

FIG. 2 is a cross-sectional view of a communications module 200, according to another embodiment of the invention. The communications module 200 illustratively includes a semiconductor substrate 202 having first and second opposing sides. A baseband layer 204 comprising baseband circuitry (not explicitly shown) and an RF layer 206 adjacent the baseband layer comprising RF circuitry (not explicitly shown) can be formed within the semiconductor substrate 202.

The, communications module 200 further illustratively includes a gallium nitride (GaN) layer 208 disposed on the first side of the substrate. Within the GaN layer 208 at least one power amplifier (not explicitly shown) can be formed. A metal ground plane 210 is illustratively disposed on the second side of the substrate 202, the metal ground plane having first and second opposing sides. As shown, the first side of the ground plane 210 is adjacent to the second side of the substrate 202. A dielectric layer 212 of low thermal dielectric material is deposited on the back side of the ground plane 210. A dual-function antenna-heatsink structure 214 is bonded to the dielectric layer 212. At least one via 216 illustratively extends from the dual-function heatsink-antenna structure 214 through the dielectric layer 212 to the metal ground plane 210.

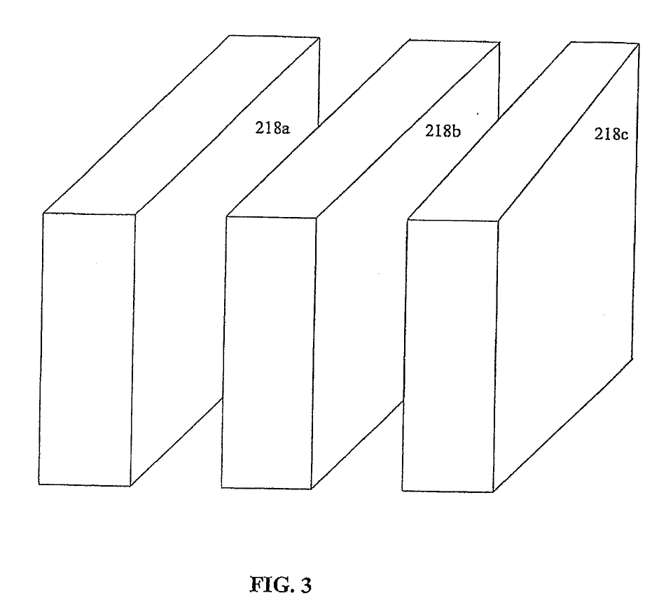

The dual-function heatsink-antenna structure 214 performs the dual functions of conducting energy associated with the transmission and receiving of communications signals while also dissipating heat generated within the communications module 200. According to a particular embodiment, the dual-function heatsink-antenna 214 comprises a plurality of spaced-apart, heat-dissipating extensions 218a-c extending outwardly from the communications module for both dissipating heat and conducting RF energy to and from the RF circuitry. The extensions are shown in perspective view in FIG. 3 and are described more particularly below in the context of additional embodiments of the invention.

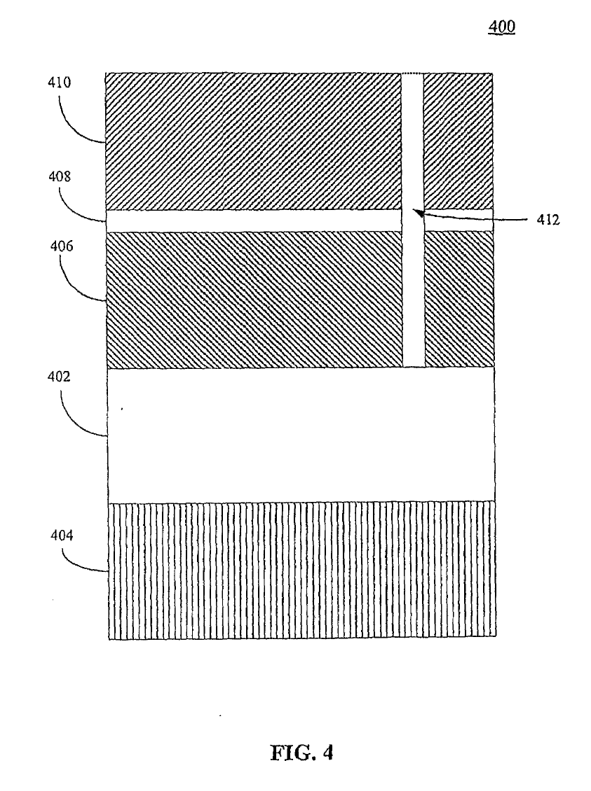

FIG. 4 is a cross-sectional view of a data processing module 400, according to still another embodiment of the invention. The data processing module 400 illustratively includes a semiconductor substrate 402 having first and second opposing sides. An integrated array of passive and active elements comprising data processing circuitry (not explicitly shown) that operates as a central processing unit (CPU) can be formed within the semiconductor substrate 402.

The data processing module 400 further illustratively includes a gallium nitride (GaN) layer 404 disposed on the first side of the semiconductor substrate 402. At least one power amplifier (not explicitly shown) also can be formed within the GaN layer 404 for powering the CPU.

A metal ground plane 406 is illustratively disposed on the second, opposing side of the semiconductor substrate 402, the ground plane also has first and second opposing sides. As shown, the first side of the ground plane 406 is adjacent to the second side of the semiconductor substrate 402. A dielectric layer 408 of low thermal dielectric material is deposited on the back side of the ground plane 406. A heatsink 410 is bonded to the dielectric layer 408. As further illustrated, at least one via 412 extends through the heatsink 410, dielectric layer 408, and ground plane 406 to the semiconductor substrate 402. The via 412 can be used to connect the CPU to an external component.

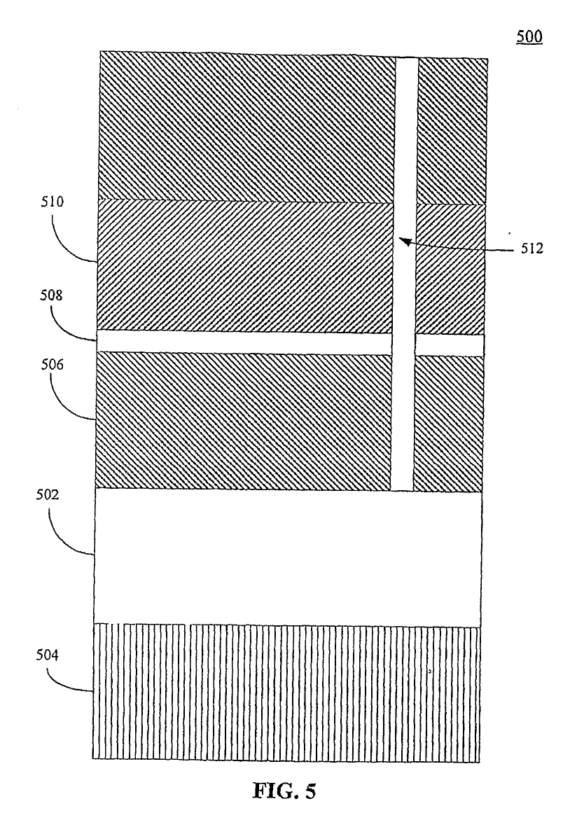

FIG. 5 is a cross-sectional view of an alternative data processing module 500, according to a different embodiment. In the embodiment illustrated in FIG. 5, a semiconductor substrate 502 again has first and second opposing sides and further includes an integrated array of passive and active elements comprising data processing circuitry (not explicitly shown) that operates as a central processing unit (CPU). A gallium nitride (GaN) layer 504 is disposed on the first side of the semiconductor substrate 502 and can include a power amplifier (not explicitly shown) formed therein for powering the CPU.

According to this embodiment, a first metal ground plane 506 is illustratively disposed on the second, opposing side of the semiconductor substrate 502. The first ground plane 506, as illustrated, also has first and second opposing sides, with the first side being adjacent to the second side of the semiconductor substrate 502. A dielectric layer 508 of low thermal dielectric material is deposited on the back side of the ground plane 506. A second metallic ground plane 510 is bonded to the dielectric layer 508, such that the dielectric layer is disposed between the first ground plane 506 and the second ground plane. A heatsink 512 is connected to an opposing side of the second ground plane 510. As further illustrated, at least one via 514 extends through the heatsink 512, dielectric layer 508, and both ground planes 506, 510, to the semiconductor substrate 502. As in the previous embodiment, the at least one via 514 can be used to connect the CPU to an external component.

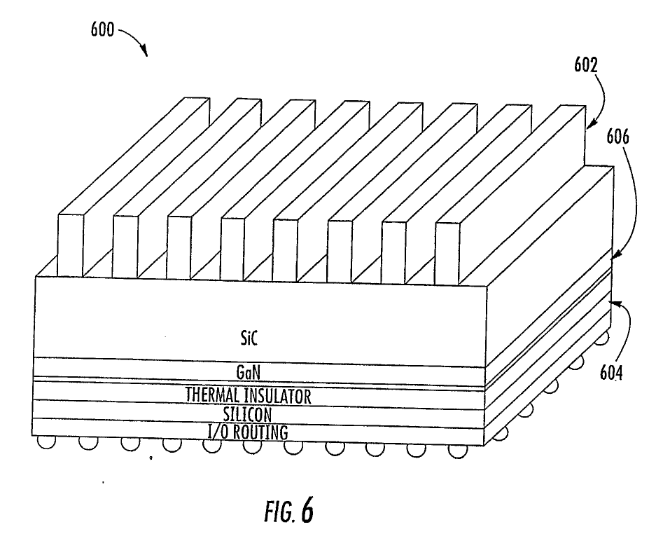

Referring now to FIG. 6, an integrated circuit 600 for effecting RF communications, according to yet another embodiment of the invention, is schematically illustrated. The circuit 600 illustratively includes a dual-function heatsink-antenna structure 102. More particularly, the integrated circuit 600 is a three-dimensional system-on-chip (SOC) that further includes a first portion 604, in which is embedded baseband circuitry, and a second portion 606 in which is embedded RF circuitry. As used herein, embedded elements include elements disposed on a substrate or at least partially contained within the substrate.

As will be readily understood one of ordinary skill in the art, the baseband circuitry embedded in the first portion 604 generates and/or receives an analog or a digital signal, as will be readily understood by one of ordinary skill. The RF circuitry embedded in the second portion 606 generates and/or receives an RF frequency signal, as will also be. readily understood by one of ordinary skill. Both the baseband circuitry and the RF circuitry can be implemented in one or more dedicated hardwired circuits, or alternatively, in a combination of dedicated circuitry and machine-readable code configured to run on a computing element that is connected with, or incorporated in, the remainder of the RF circuitry.

The first portion 604 and the second portion 606 in which are embedded the baseband and RF circuitry, respectively, each illustratively comprise a semiconductor substrate. Optionally, the semiconductor substrates forming the first portion 604 and the second portion 606 of the integrated circuit 600 can be separated by a layer of thermal insulation. More particularly, the thermal insulation layer can be disposed on a top surface of the first portion 604, and the second portion 606 can be disposed on a top surface of the thermal layer in stacked formation, similar to that described above.

The thermal insulation layer can, at least partially, insulate the baseband circuitry in the first portion 604 from heat generated by the RF circuitry in the second portion 606 of the integrated circuit. The dual-function heatsink-antenna structure 602 has the dual functions of dissipating heat, especially that generated by a power amplifier for RF transmissions, while also providing a conductor for the radiation and/or receipt of RF energy; that is, the heatsink-antenna structure 602 dissipates heat while also providing an antenna for transmitting and/or receiving RF communication signals.

The dual-function heatsink-antenna structure 602 is illustratively disposed on, or partially contained in, the second portion 206 of the integrated circuit 600. Accordingly, the dual-function heatsink-antenna structure 602 is advantageously positioned close to the RF circuitry embedded in the second portion 106 of the integrated circuit 600. This close positioning of the dual-function heatsink-antenna structure 602 relative to the RF circuitry enhances thermal efficiency in terms of heat dissipation as well as efficiency with which RF signals transmitted from and/or received by the dual-function heatsink-antenna structure 602 and conveyed to the RF circuitry.

According to one embodiment, the dual-function heatsink-antenna structure 602 comprises a plurality of spaced-apart conducting and heat-dissipating elements. The components of the dual-function heatsink-antenna structure 602, more particularly, can comprise a plurality of elongated rectangular elements spaced apart from one another and disposed on or partially embedded in the second portion 606 of the dual-function circuit 600. (See also FIG. 3.) At least one of the spaced-apart components of the dual-function heatsink-antenna structure 602 acts as a conductor for radiating and/or receiving RF energy corresponding to the transmission and/or receipt of a wireless communications signal. At least one other of the components of the dual-function heatsink-antenna structure 602 acts a thermal conductor for dissipating heat. Preferably, each of the spaced-apart components of the dual-function heatsink-antenna structure 102 is a thermal conductor that also radiates and/or receives RF energy.

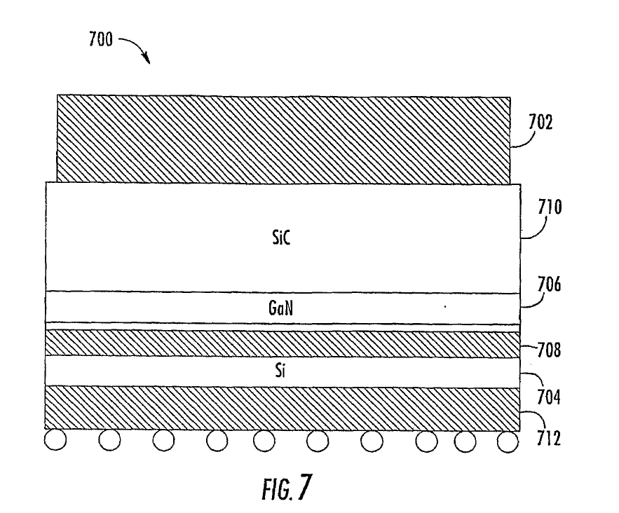

Referring now to FIG. 7, an integrated circuit 700 for effecting RF communications, according to another embodiment of the invention, is illustrated. The integrated circuit 700 illustratively includes an dual-function heatsink-antenna structure 702. As already described the dual-function heatsink-antenna structure 702 can comprise a plurality of spaced-apart elements for conducting thermal energy, as well as for radiating and/or receiving RF energy.

The integrated circuit 700 further includes a layer in which is embedded baseband circuitry. According to one embodiment of the layer in which the baseband circuitry is embedded comprises a silicon (Si) layer 704, or a layer of similar semiconductor material. The integrated circuit also includes a layer in which is embedded RF circuitry. According to this embodiment, the layer in which the RF circuitry is embedded comprises a gallium nitride (GaN) layer 706.

The dual-function heatsink-antenna structure 702 dissipates heat generated by the RF circuitry and, as shown, is advantageously positioned close to the RF circuitry. Again, the positioning of the dual-function heatsink-antenna structure 702 close to the RF circuitry not only enhances efficiency in terms of heat dissipation but also enhances the efficiency with which RF signals transmitted from and received by the heatsink-antenna structure are conveyed to the RF circuitry.

The Si layer 704 in which the baseband circuitry is embedded and the GaN layer 706 in which the RF circuitry is embedded are illustratively separated from one another by a thermal insulation layer 708. The insulation layer 708, as already described, can provide some degree of heat protection for the baseband circuitry in the Si layer.

The integrated circuit 700 further comprises another semiconductor layer that is illustratively disposed on a top surface of the GaN layer 706. The semiconductor layer according to this embodiment comprises a silicon carbide layer (SiC) 710. Silicon carbide is known to have high thermal conductivity, and accordingly, the SiC layer 710 provides good thermal coupling between the RF circuitry in the GaN layer 706 and the dual-function heatsink-antenna structure 702. This enhances the transfer of heat generated by the RF circuitry in the GaN layer 706 to the dual-function heatsink-antenna structure 702 positioned in close proximity thereto.

The SiC can be also be used as the dielectric for an antenna similar in structure to a microstrip patch antenna. Functionally, the antenna will serve as a heatsink as well as an electromagnetic radiator. Directly below the GaN layer is a thin ground layer which will provide a ground plane for the antenna as well as the electronics.

Additionally, according to this embodiment, the integrated circuit 700 includes yet another semiconductor layer. The semiconductor layer defines an I/O routing layer 712 in which is embedded circuitry for performing I/O routing functions. The I/O routing layer 712 contains metal interconnects to distribute signals from Si layer 704 to the ball grid array that makes the connection to a printed circuit board.

Although an integrated circuit for effecting communications according to an embodiment of the invention has been described primarily in terms of transmitting and receiving RF signals, the invention is not limited in this respect. Indeed, the invention more generally encompasses an integrated circuit for transmitting and receiving signals conveyed by electromagnetic waves not limited to the RF range. Such a circuit, according to another embodiment, includes one or more semiconductor layers, and transceiver circuitry embedded in at least one semiconductor layer, as described above. A dual-function antenna-and-heatsink structure is disposed on the semiconductor layer, as also described above. The dual-function antenna-and-heatsink structure dissipates heat from the semiconductor layer and also conducts electromagnetic energy to and from the semiconductor layer

The embodiments described herein are merely illustrative of the various applications of the invention. The invention can be embodied in other forms without departing from the spirit or essential attributes thereof. Accordingly, reference should be made to the following claims, rather than to the foregoing specification, as indicating the scope of the invention.

We claim:

1. A multi-layer heatsink module for effecting temperature control in a three-dimensional integrated chip, the module comprising:
a high thermal conductivity substrate having first and second opposing sides;
a gallium nitride (GaN) layer disposed on the first side of said substrate, said GaN layer having formed therein an integrated array of passive and active elements defining electronic circuitry;
a metal ground plane disposed on the second side of said substrate, said metal ground plane having first and second opposing sides, said first side of said ground plane adjacent the second side of said substrate;
a dielectric layer of low thermal dielectric material deposited on the back side of said ground plane;
a metal heatsink bonded to said dielectric layer; and
at least one via extending through said dielectric layer from said metal heatsink to said metal ground plane.

2. The module of claim 1, wherein the electronic circuitry comprises at least one power amplifier.

3. The module of claim 1, wherein the dielectric layer has a thickness within a range of 0.5 micrometers (μm) to 1.5 micrometers (μm).

4. The module of claim 1, wherein the dielectric material comprises silicon oxide (siO₂).

5. The module of claim 1, wherein the dielectric material comprises titanium oxide (TiO₂).

6. The module of claim 1, wherein the substrate comprises a silicon-based material.

7. The module of claim 4, wherein the substrate comprises silicon carbide (SiC).

8. The module of claim 1, wherein the heatsink comprises at least one extension forming an antenna that extends outwardly from the module, and wherein the substrate includes communication circuitry formed therein.

9. A communications module, comprising
a semiconductor substrate having first and second opposing sides, said substrate having formed therein a baseband layer comprising baseband circuitry and an RF layer adjacent the baseband layer comprising RF circuitry;
a gallium nitride (GaN) layer disposed on the first side of said substrate, said GaN layer having formed therein at least one power amplifier;
a metal ground plane disposed on the second side of said substrate, said metal ground plane having first and second opposing sides, said first side of said ground plane adjacent the second side of said substrate;
a dielectric layer of low thermal dielectric material deposited on the back side of said ground plane;
an integrated heatsink-antenna structure bonded to said dielectric layer; and
at least one via extending from said integrated heatsink-antenna structure through said dielectric layer to said metal ground plane.

10. The communications module of claim 9, wherein the integrated heatsink-antenna structure comprises a plurality of spaced-apart heat-dissipating extensions extending outwardly from the communications module.

11. The communications module of claim 9, wherein the dielectric layer has a thickness within a range of 0.5 micrometers (μm) to 1.5 micrometers (μm).

12. The module of claim 9, wherein the dielectric material comprises silicon oxide (SiO₂).

13. The module of claim 9, wherein the dielectric material comprises (TiO₂).

14. The module of claim 9, wherein the RF circuitry comprises an RF receiver.

15. The module of claim 9, wherein the RF circuitry comprises an RF transmitter.

16. A data processing module, comprising
a semiconductor substrate having first and second opposing sides, said substrate having formed therein an integrated array of passive and active elements data processing circuitry defining a central processing unit;
a gallium nitride (GaN) layer disposed on the first side of said substrate, said GaN layer having formed therein at least one power amplifier;
a metal ground plane disposed on the second side of said substrate, said metal ground plane having first and second opposing sides, said first side of said ground plane adjacent the second side of said substrate;
a dielectric layer of low thermal dielectric material deposited on the back side of said ground plane;
a metal ground plane bonded to said dielectric layer; and
at least one via extending from through said ground plane and dielectric layer to said semiconductor substrate for connecting the central processing unit to an external component.

17. The data processing module of claim 16, wherein the electronic circuitry comprises at least one power amplifier.

18. The data processing module of claim 16, wherein the dielectric layer has a thickness within a range of 0.5 micrometers (μm) to 1.5 micrometers (μm).

19. The data processing module of claim 16, wherein the dielectric material comprises silicon oxide (SiO₂).

20. The data processing module of claim 16, wherein the dielectric material comprises (TiO₂).

21. An integrated circuit for effecting radio frequency (RF) communications, the integrated circuit comprising:
at least one semiconductor layer, defining a baseband layer, containing baseband circuitry;
at least one additional semiconductor layer, defining an RF layer, containing RF circuitry and being positioned adjacent the baseband layer; and
a dual-function heatsink-and-antenna structure embedded in the RF layer for dissipating heat and for conducting RF energy.

22. The integrated circuit of claim 21, wherein the integrated heatsink-antenna structure comprises a plurality of spaced-apart heat-dissipating elements disposed on the RF layer.

23. The integrated circuit of claim 22, wherein at least one of the spaced-apart heat-dissipating elements comprises an elongated rectangular structure.

24. The integrated circuit of claim 21, further comprising an I/O routing layer adjacent the baseband layer.

25. The integrated circuit of claim 21, further comprising a thermal insulating layer disposed between the baseband layer and the adjacent RF layer for thermally protecting at least the baseband layer.

26. The integrated circuit of claim 21, wherein the baseband layer comprises silicon.

27. The integrated circuit of claim 21, wherein the at least one additional semiconductor layer defining the RF layer comprises a first RF layer and a second RF layer.

28. The integrated circuit of claim 27, wherein the first RF layer comprises a silicon carbide (SiC) layer.

29. An integrated circuit for transmitting and receiving signals conveyed by electromagnetic waves, the integrated circuit comprising:
a semiconductor layer;
transceiver circuitry embedded in the semiconductor layer; and
a dual-function antenna-and-heatsink structure disposed on the semiconductor layer to dissipate heat from the semiconductor layer and to conduct electromagnetic energy to and from the semiconductor layer.

30. An integrated circuit for effecting radio frequency (RF) communications, the integrated circuit comprising:
a first semiconductor portion containing baseband circuitry;
a second semiconductor portion containing RF circuitry adjacent the first semiconductor portion; and
a plurality of spaced-apart elements disposed on the second semiconductor layer portion, each of the spaced-apart elements conducting RF energy to and from the RF circuitry contained in the second semiconductor portion and dissipating heat from the first and second semiconductor portions.
